(19) United States
(12) Patent Application Publication
(10) Pub. No.: US 2008/0088353 A1
(43) Pub. Date: Apr. 17, 2008

(54) LEVEL SHIFTER CIRCUIT WITH CAPACITIVE COUPLING

(76) Inventor: Chun-Hung Kuo, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/549,126

(22) Filed: Oct. 13, 2006

(51) Int. Cl. H03L 5/00

(52) U.S. Cl. 327/333

(57) ABSTRACT

A level shifter circuit uses capacitive coupling to level shift a signal. The level shifter circuit has a capacitor, an input switch coupled to a first input and a first terminal of the capacitor, a second switch coupled to a second input and the first terminal of the capacitor, and a third switch coupled to the first input and a second terminal of the capacitor.

### BACKGROUND OF THE INVENTION

1. Field of the Invention

The present invention relates to level shifter circuits used in video driver circuits, and more particularly, to a level shifter circuit with capacitive coupling.

2. Description of the Prior Art

In modern computing systems, a shift has occurred from traditional cathode ray tube (CRT) monitors to liquid crystal display (LCD) panels. Where CRT monitors are bulky and typically have a slightly rounded display surface, LCD panels are slim and inherently flat. Of course, due to their size, LCD panels are also lighter than their CRT counterparts, making them easier to transport safely during installation.

Due to a large difference between LCD panel technology and CRT technology, a demand for improved circuit architectures and topologies has arisen. Please refer to FIG. 1, which is a diagram of a horizontal driver circuit architecture 100 according to the prior art. The horizontal driver circuit architecture shown in FIG. 1 is disclosed by Yoshiharu Nakajima in U.S. Pat. No. 6,664,943. For simplicity, one path is shown in FIG. 1. The horizontal driver circuit 100 comprises a horizontal shift register 101, a sampling/first latch circuit 102, a second latch 103, a level shifter 104, a digital-to-analog converter (DAC) 105, and an effective pixel area 106. An output of the horizontal shift register 101 provides a sampling pulse to the sampling/first latch circuit 102, according to which the sampling/first latch circuit 102 samples a digital input signal Vin and stores data of the digital input signal Vin. In order to accommodate operation of the DAC 105, the level shifter 104 increases a range of the digital input signal. For example, where as the digital input signal Vin may have an original range of 0-1.8V or 0-3V, the level shifter 104 will increase the range of the digital input signal Vin to 0-9V, or more preferably, to −3-6V.

Please refer to FIG. 2, which shows a first latch 20 and a second latch 22 according to the prior art. FIG. 2 is disclosed by Yoshiharu Nakajima in SID Symposium Digest of Technical Papers, May 2004, Volume 35, Issue 1, pp. 864-867. In the prior art, the function of the level shifter 104 mentioned above can be realized in the first latch 20 and the second latch 22. The first latch 20 increases the range of the digital input signal Vin in a positive direction from 0-3V to 0-6V. Then, the second latch 22 increases the range of the digital input signal Vin from 0-6V to −3-6V. Although this circuit architecture eliminates a need for the level shifter 104, the first latch 20 and the second latch 22 consume a relatively large amount of power. This is because when the first latch 20 amplifies the digital input signal Vin to 0-6V, a DC current is generated in the first latch 20. Likewise, when the second latch 22 shifts the digital input signal Vin to −3-6V, a DC current is generated in the second latch 22.

### SUMMARY OF THE INVENTION

According to the present invention, a level shifter circuit comprises a capacitor, a first switch coupled to a first input and a first terminal of the capacitor, a second switch coupled to a second input and the first terminal of the capacitor, and a third switch coupled to the first input selectively and coupled to a second terminal of the capacitor.

According to the present invention, another level shifter circuit comprises a capacitor, a first switch coupled to an output of an inverter and a first terminal of the capacitor, a second switch coupled to an input of the inverter and the first terminal of the capacitor, and a third switch selectively coupled to the output of the inverter and coupled to a second terminal of the capacitor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a horizontal driver circuit architecture according to the prior art.

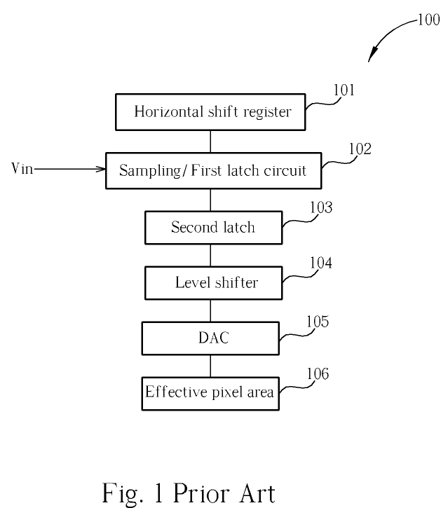

FIG. 2 is a diagram of a level shifter circuit according to the prior art.

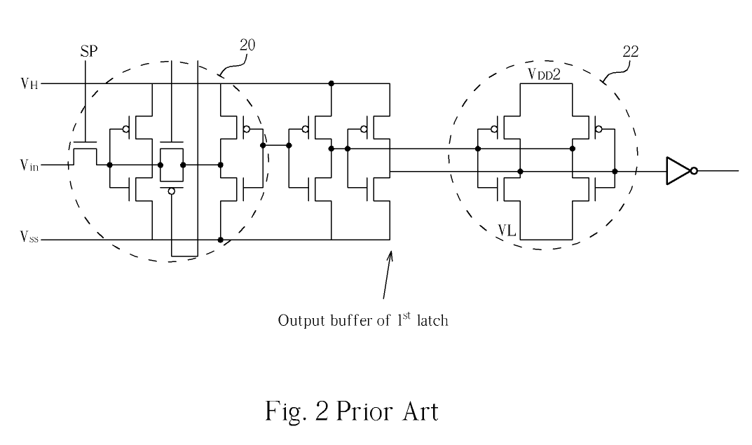

FIG. 3 is a diagram of a level shifter circuit according to a first embodiment of the present invention.

FIG. 4 is a waveform of a sampling signal and an output enable signal according to the present invention.

FIG. 5 is a diagram of a level shifter circuit according to a second embodiment of the present invention.

FIG. 6 is a diagram of a level shifter circuit according to a third embodiment of the present invention.

FIG. 7 is a diagram of a level shifter circuit according to a fourth embodiment of the present invention.

### DETAILED DESCRIPTION

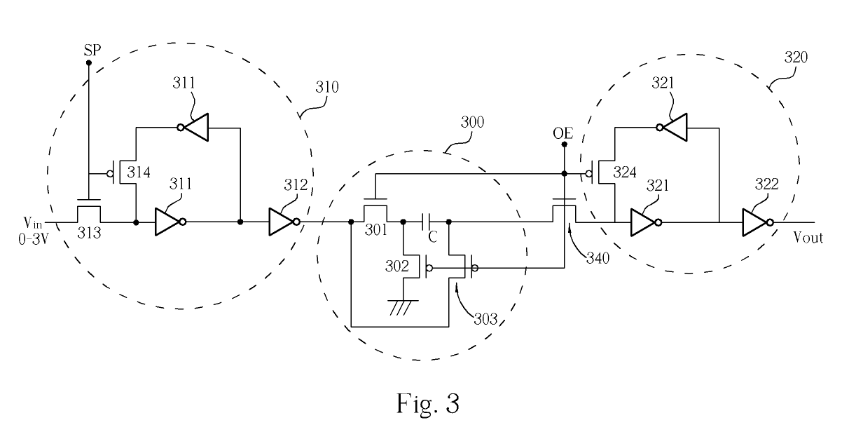

Please refer to FIG. 3, which is a diagram of a level shifter 300 according to a first embodiment of the present invention. The level shifter 300 is preceded by a first latch 310 and followed by a second latch 320. The first latch 310 comprises two latch inverters 311 and an output inverter 312. Likewise, the second latch 320 comprises two latch inverters 321 and an output inverter 322. The first latch 310 further comprises a sampling switch 313 and a latch enable switch 314, both of which are controlled, i.e. enabled or disabled, by a sampling signal SP. The sampling switch 313 is an n-type metal-oxide-semiconductor (NMOS) transistor and receives a digital input signal Vin, and the latch enable switch 314 is a p-type metal-oxide-semiconductor (PMOS) transistor. The second latch 320 further comprises a latch enable switch 324, which is also a PMOS transistor. The level shifter 300 comprises an input switch 301 coupled to an output of the output inverter 312 of the first latch 310, a capacitor C coupled to the input switch 301, a second switch 302 coupled between a first terminal of the capacitor C and a second input (as shown, ground), and a third switch 303 coupled between a second terminal of the capacitor C and the output of the output inverter 312 of the first latch 310. The output of the output inverter 312 of the first latch 310 is an input having a voltage substantially the same as a voltage of the first input. An output enable switch 340 is coupled between the second terminal of the capacitor C and the second latch 320, and is controlled, i.e. enabled or disabled, by an output enable signal OE. The input switch 301, the second switch 302, the third switch 303, and the latch enable switch 324 are all controlled by the output enable signal OE. As shown, the input switch 301 and the output enable switch 340 are both NMOS transistors, and the second switch 302 and the third switch 303 are both PMOS transistors.

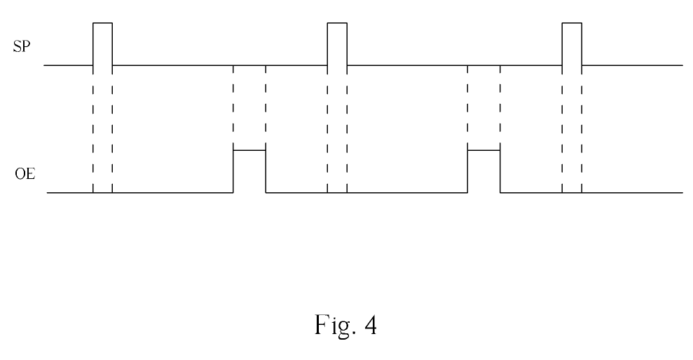

For description of operation of the level shifter 300 shown in FIG. 3, please refer to FIG. 4, which is a waveform of the sampling signal SP and the output enable signal OE according to an embodiment of the present invention. The sampling signal SP is initially high to enable the sampling switch 31 3, so as to transfer a voltage of a digital input signal Vin to the first latch 310. When the sampling signal SP is low, the sampling switch 313 is disabled and the latch enable switch 314 is enabled. Thus, the voltage of the digital input signal Vin is inverted twice, and is held at the output of the output inverter 312 of the first latch 310 to be received by the level shifter 300. In the present embodiment, the first latch 310 can operate at a same voltage range as that of the digital input signal Vin. In other words, assuming the digital input signal Vin has a voltage range of 0-3V, the first latch 310 of the present invention can also operate in the voltage range of 0-3V, as opposed to operating in a voltage range of 0-6V used in the prior art. In this way, the present invention reduces DC current consumed in the first latch 20.

Refer to FIG. 4. Because the output enable signal OE is initially low, as soon as the voltage of the digital input signal Vin is transferred to the output of the output inverter 312 of the first latch 310, the voltage is also transferred via the third switch 303 of the level shifter 300 to the second terminal of the capacitor C. Of course, the first terminal of the capacitor C is grounded via the second switch 302, which is also enabled by the output enable signal OE. As such, if the voltage of the digital input signal Vin is high, a voltage drop is present from the second terminal of the capacitor C to the first terminal of the capacitor C. When the output enable signal OE is high, the second switch 302 and the third switch 303 are disabled, and the voltage of the digital input signal Vin is transferred to the first terminal of the capacitor C. Again, assuming the voltage of the digital input signal Vin is high, the first terminal of the capacitor C, which was initially grounded, begins to charge to the voltage of the digital input signal Vin. As the first terminal of the capacitor C charges, to maintain the voltage drop from the second terminal to the first terminal of the capacitor C, the second terminal of the capacitor C must be applied with increased voltage. When the first terminal of the capacitor C has reached the voltage of the digital input signal Vin, the second terminal of the capacitor C then holds a level shifted voltage that is double of the voltage of the digital input signal Vin. This level shifted voltage is transferred via the output enable switch 340 to the second latch 320, and appears as an output voltage Vout at an output of the second latch 320. At this point, the output enable signal OE is low, the first terminal and the second terminal of the capacitor C discharge, and the output voltage Vout is maintained by the second latch 320. Of course, it would be obvious to one familiar with the art that, in the configuration shown in FIG. 3, if the voltage of the digital input signal Vin were low, i.e. 0V, then the output voltage Vout would be maintained at 0V. Thus, as shown, the first embodiment of the present invention provides a level shift from, for example, 0-3V to 0-6V, while reducing power consumed by the level shifter and the first latch.

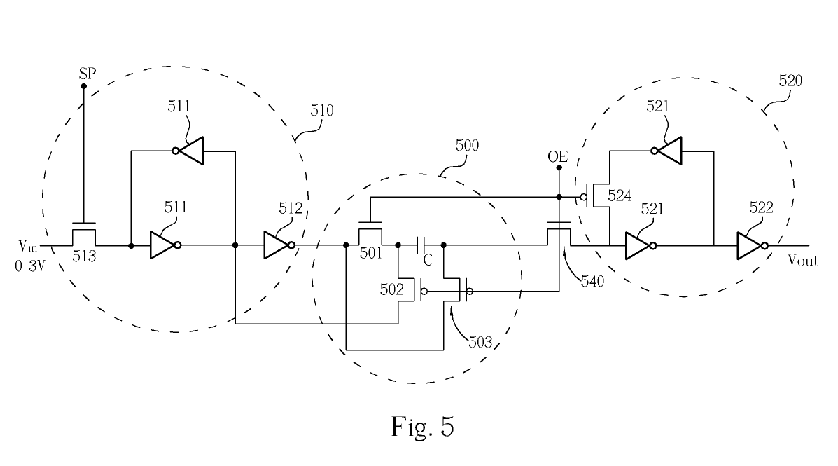

Please refer to FIG. 5, which is a diagram of a level shifter 500 according to a second embodiment of the present invention. The level shifter 500 is preceded by a first latch 510 and followed by a second latch 520. The first latch 510 comprises two latch inverters 511 and an output inverter 512. Likewise, the second latch 520 comprises two latch inverters 521 and an output inverter 522. The first latch 510 further comprises a sampling switch 513, which is controlled, i.e. enabled or disabled, by a sampling signal SP. The sampling switch 513 is an NMOS transistor and receives a digital input signal Vin. The second latch 520 further comprises a latch enable switch 524, which is a PMOS transistor. The level shifter 500 comprises an input switch 501 coupled to an output of the output inverter 512 of the first latch 510, a capacitor C coupled to the input switch 501, a second switch 502 coupled between a first terminal of the capacitor C and a second input (as shown, an input of the output inverter 512), and a third switch 503 coupled between a second terminal of the capacitor C and the output of the output inverter 512 of the first latch 510. An output enable switch 540 is coupled between the second terminal of the capacitor C and the second latch 520, and is controlled, i.e. enabled or disabled, by an output enable signal OE. The input switch 501, the second switch 502, the third switch 503, and the latch enable switch 524 are all controlled by the output enable signal OE. As shown, the input switch 501 and the output enable switch 540 are both NMOS transistors, and the second switch 502 and the third switch 503 are both PMOS transistors.

Operation of the level shifter 500 can be described according to the waveform diagram in FIG. 4. Please refer again to FIG. 4. The sampling signal SP initially is high to enable the sampling switch 513, so as to transfer the voltage of the digital input signal Vin to the first latch 510. When the sampling signal SP is low, the sampling switch 513 is disabled. Thus, the voltage of the digital input signal Vin is inverted twice, and is held at the output of the output inverter 512 of the first latch 510 to be received by the level shifter 500. The first latch 510 of the present invention can operate at the same voltage range as that of the digital input signal Vin. In other words, assuming the digital input signal Vin has the voltage range of 0-3V, the first latch 510 of the present invention can also operate in the voltage range of 0-3V. In this way, the present invention reduces DC current consumed in the first latch 20.

Refer to FIG. 4. Because the output enable signal OE is initially low, as soon as the voltage of the digital input signal Vin is transferred to the output of the output inverter 512 of the first latch 510, the voltage is also transferred via the third switch 503 of the level shifter 500 to the second terminal of the capacitor C. As a further improvement over the first embodiment described above, in the second embodiment, the first terminal of the capacitor C is initially charged/discharged to an inverted level of the voltage of the digital input signal Vin via the second switch 502, which is also enabled by the output enable signal OE. As such, if the voltage of the digital input signal Vin is high, then the voltage drop mentioned above is present from the second terminal of the capacitor C to the first terminal of the capacitor C. However, if the voltage of the digital input signal Vin is low, then a voltage drop from the first terminal of the capacitor C to the second terminal of the capacitor C is present in the second embodiment of the present invention. When the output enable signal OE is high, the second switch 502 and the third switch 503 are disabled, and the voltage of the digital input signal Vin is transferred to the first terminal of the capacitor C. Again, assuming the voltage of the digital input signal Vin is high, the first terminal of the capacitor C, which was initially low, begins to charge to the voltage of the digital input signal Vin. As the first terminal of the capacitor C charges, to maintain the voltage drop from the second terminal to the first terminal of the capacitor C, the second terminal of the capacitor C must be applied with increased voltage. When the first terminal of the capacitor C has reached the voltage of the digital input signal Vin, the second terminal of the capacitor C then holds a level shifted voltage that is double the voltage of the digital input signal Vin. Of course, assuming the voltage of the digital input signal Vin is low, the first terminal of the capacitor C, which was initially high, begins to discharge to the voltage of the digital input signal Vin. As the first terminal of the capacitor C discharges, to maintain the voltage drop from the first terminal to the second terminal of the capacitor C, the second terminal of the capacitor C must be applied with decreased voltage. In this way, the second terminal of the capacitor C is driven to a voltage that is lower than low by a voltage difference between high and low in the digital input signal Vin. This level shifted voltage is transferred via the output enable switch 540 to the second latch 520, and appears as an output voltage Vout at an output of the second latch 520. At this point, the output enable signal OE is low, the first terminal and the second terminal of the capacitor C discharge, and the output voltage Vout is maintained by the second latch 520. Of course, in the configuration shown in FIG. 5, if the voltage of the digital input signal Vin were low, i.e. 0V, and the inverted voltage were high, i.e. 3V, then the output voltage Vout would be driven down to −3V. Thus, as shown, the second embodiment of the present invention provides a level shift from, for example, 0-3V to −3-6V, while reducing power consumed by the level shifter and the first latch.

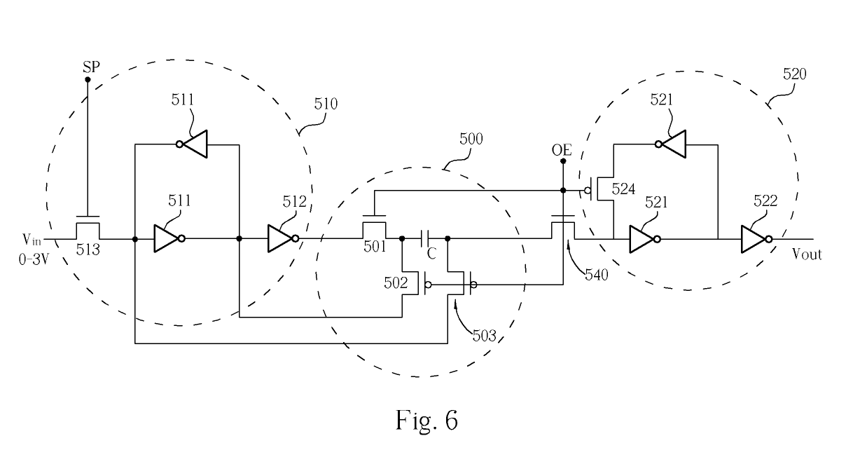

Please refer to FIG. 6 for a third embodiment of the level shifter circuit according to the present invention. Without repeating the discussion above, one major difference between the third embodiment shown in FIG. 6 and the above described embodiments is that the third switch 503 is coupled between the second terminal of the capacitor C and the output of the sampling switch 513, i.e. the input of the first latch 510.

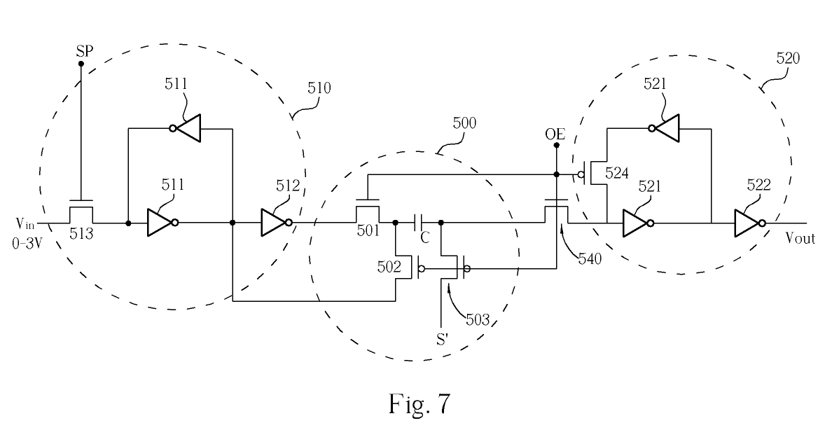

Please refer to FIG. 7, which shows a fourth embodiment of the level shifter circuit according to the present invention. In the fourth embodiment shown in FIG. 7, the third switch 503 is coupled between the second terminal of the capacitor C and an input S′. The input S′ is an input having a state different from a state of the second input (as shown, an input of the output inverter 512). In other words, if the state of the second input is HIGH, e.g. 3.3V, then the state of the input S′ is LOW, e.g. 0V; if the state of the second input is LOW, e.g. 0V, then the state of the input S′ is HIGH, e.g. 3.3V. The third embodiment shown in FIG. 6 is one realization of this configuration. Any configuration where the second input has a state that is different from the state of the input S′, i.e. the third input, fits the spirit of the present invention.

The PMOS transistors and the NMOS transistors mentioned above could all be changed to NMOS transistor and PMOS transistors, respectively, and the sampling signal SP and the output enable signal OE could be changed from active high to active low. Of course, other transistor technologies could also be employed, such as BJT technology. However, thin film transistors are preferred for application to LCD panels. Finally, the second switches 302, 502 and the third switches 303, 503 mentioned above could also be controlled by the sampling signal SP. Any of these modifications could be made to the present invention without deviating from the spirit of the present invention in any of its embodiments.

Those skilled in the art will readily observe that numerous modifications and alterations of the device and method may be made while retaining the teachings of the invention. Accordingly, the above disclosure should be construed as limited only by the metes and bounds of the appended claims.

1. A level shifter circuit comprising:
a capacitor;
an input switch coupled to a first terminal of the capacitor and a first input;
a second switch coupled to a second input and the first terminal of the capacitor; and
a third switch coupled to a second terminal of the capacitor.

2. The level shifter circuit of claim 1, wherein the second input is ground.

3. The level shifter circuit of claim 1, wherein the input switch is an n-type metal-oxide-semiconductor (NMOS) transistor, the second switch is a p-type metal-oxide-semiconductor (PMOS) transistor, the third switch is a PMOS transistor, and gates of the first, second, and third switches are coupled together.

4. The level shifter of claim 1, wherein the third switch is further coupled to an input having a voltage substantially the same as a voltage of the first input.

5. The level shifter of claim 1, wherein the third switch is further coupled to the first input.

6-10. (canceled)

11. A driver circuit comprising:
a shift register;
a first latch circuit electrically coupled to the shift register;
the level shifter of claim 1 electrically coupled to the first latch circuit;
a second latch circuit electrically coupled to the level shifter; and
a digital-to-analog converter electrically coupled to the second latch circuit.

12. (canceled)
